(19) United States
(12) Patent Application Publication
(10) Pub. No.: US 2003/0115540 A1
(43) Pub. Date: Jun. 19, 2003

(54) Base-band encoding apparatus and frequency modulation method using the same in digital broadcasting system

(76) Inventors: Jae-Hwui Bae, Daejon (KR); Jae-Hyun Seo, Daegu (KR); Seung Won Kim, Daejon (KR); Chieteuk Ahn, Daejon (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/288,910

(22) Filed: Nov. 6, 2002

(30) Foreign Application Priority Data
Dec. 14, 2001 (KR) 2001-79479

(51) Int. Cl. H04L 1/00; G06F 11/00; G06F 11/30; H03M 13/00; G08C 25/00; H03M 13/03

(52) U.S. Cl. 714/792

(57) ABSTRACT

A baseband encoding apparatus and frequency modulation method using the same in vestigial sideband (VSB) transmission system is disclosed. The apparatus includes a trellis encoder having a 1/2 code rate for generating a 2-bit output signal based on a 1-bit input signal and generating 4 types of signal levels in baseband by using the 2-bit output signal for converting the 4 types of the signal levels of the trellis encoder to symbols and generating 4 types of output symbols. The present invention can improve the receiving performance of the VSB transmission system in a mobile environment by implementing the trellis coded modulation having 1/2 code rate in the VSB broadcasting transmission system, which critically decreases minimum signal-to-noise ratio for recovering an original signal.

### FIELD OF THE INVENTION

The present invention relates to a baseband encoding apparatus in a digital broadcasting system, a frequency modulating method by using the baseband encoding apparatus and a computer readable recoding medium storing instructions for executing the same method; and more particularly to, a baseband encoding apparatus and frequency modulating method using the same for improving a threshold of visibility (TOV), which is a minimum signal-to-noise ratio for decoding to an original signal of a digital television (DTV), by modifying a construction of a trellis coded modulation (TCM) decoder in a vestigial sideband (VSB) transmission system, which is one of the DTV transmission modes.

### DESCRIPTION OF RELATED ARTS

In general, a mobile channel has a rayleigh fading channel characteristic in which there is almost no difference between amplitudes of a main path and multipath, and a frequency selective low speed fading variable channel characteristic. By affection of the above-mentioned characteristics, a main path signal for a channel equalizer does not perfectly detect and does not completely persuades a variable channel characteristic in the 8-vestigial sideband (VSB) transmission system. Also, a detection-error and a pursuit-error occur in an output signal of an equalizer. The errors cause an ambient noise of the transmission channel or new independent noise and the above-mentioned noises cause to increase a threshold of visibility (TOV), which is the minimum signal-to-noise ratio for decoding to the original signal of the digital television (DTV). Therefore, the convention 8-VSB transmission system is not suitable in the mobile broadcasting service due to the comparatively high TOV.

The channel equalizer implemented to the VSB transmission system needs to eliminate a mutual interference of a multipath receiving signal in the mobile channel environment and to compensate a current change of the receiving signal in accordance with the variable channel characteristic. However, a conventional channel equalizer implemented in the DTV receiver of the VSB mode does not completely eliminate the receiving signal of undesired path during detecting the signal of the main path in the mobile environment and does not perfectly compensate a current variation of the receiving signal in accordance with the variable channel characteristic. The uneliminated receiving signal of the undesired path and uncompensated current variation of the receiving signal affects the main signal as the noise and it causes increasing the TOV. Therefore, the receiving performance of the conventional DTV receiver is decreased.

For deceasing the TOV, the performance of channel equalizing is necessary to be improved for effectively eliminating the signal of the multipath and persuading channel variation and also new modulation method for more reliable to noise in a baseband is required.

The conventional VSB modulation method in an advanced television systems committee (ATSC) standard 8-VSB transmission system may increase frequency efficiency however, in the mobile environment, it has many technical difficulties to implement due to comparatively high TOV value according to an additive white gaussian noise channel (AWGC) and increment of the TOV caused by increment of a noise level generated by the channel equalizer.

### SUMMARY OF THE INVENTION

It is, therefore, an object of the present invention to provide a baseband encoding apparatus and the signal modulating method using the baseband encoding apparatus for improving the TOV in an additive white gaussian noise (AWGN) channel by implementing a 4 constellation vestigial side band (VSB) modulation in a trellis coded modulation (TCM) encoder.

It is another object of the present invention to provide a computer readable record medium storing instructions for executing the method.

In accordance with an aspect of the present invention, there is provided a baseband encoding apparatus in vestigial sideband transmission system, including: a trellis encoder having a 1/2 code rate for generating a 2-bit output signal based on a 1-bit input signal and generating 4 types of signal levels in baseband by using the 2-bit output signal, wherein the trellis encoder includes M number of delayers and N number of binary adders and M and N are a natural number; and a symbol mapper for converting the 4 types of the signal levels of the trellis encoder to symbols and generating 4 types of output symbols.

In accordance with another aspect of the present invention, there is also provided a method for modulating frequency in a vestigial sideband transmission system, including the steps of: a) generating a 2-bit output signal based on a 1-bit input signal by using M natural number of delayers and N natural number of binary adders and generating 4 types of output levels by using said 2-bit output signals; b) converting the 4 types of output levels to symbols; and c) converting the symbols generated in step b) to frequency spectrums to be transmitted.

In accordance with still another aspect of the present invention, there is also provided a computer readable record medium storing instructions for executing a method for frequency modulation in a VSB transmission system, including the functions of: a) generating a 2-bit output signal based on a 1-bit input signal by using M natural number of delayers and N natural number of binary adders and generating 4 types of output levels by using said 2-bit output signals; b) converting the 4 types of output levels to symbols; and c) converting the symbols generated in step b) to frequency spectrums to be transmitted.

### BRIEF DESCRIPTION OF THE DRAWINGS

The above and other objects and features of the present invention will become apparent from the following description of the preferred embodiments given in conjunction with the accompanying drawings, in which:

FIG. 1 is a block diagram of a vestigial sideband (VSB) digital broadcasting transmission system in accordance with a preferred embodiment of the present invention;

FIG. 2 is a diagram illustrating a structure of receiver in a VSB transmission system in accordance with a preferred embodiment of the present invention;

FIG. 3 is a block diagram illustrating a structure of the trellis decoder 20 of a transmitter in a 8-VSB transmission system of an advanced television system committee (ATSC);

FIG. 4 is a diagram showing a baseband encoding apparatus in accordance with a preferred embodiment of the present invention; and

FIG. 5 is a graph depicting a noise margin of output symbols obtained by the 4-VSB modulation and 8-VSB modulation in accordance with a preferred embodiment of the present invention.

### DETAILED DESCRIPTION OF THE INVENTION

Other objects and aspects of the invention will become apparent from the following description of the embodiments with reference to the accompanying drawings, which is set forth hereinafter.

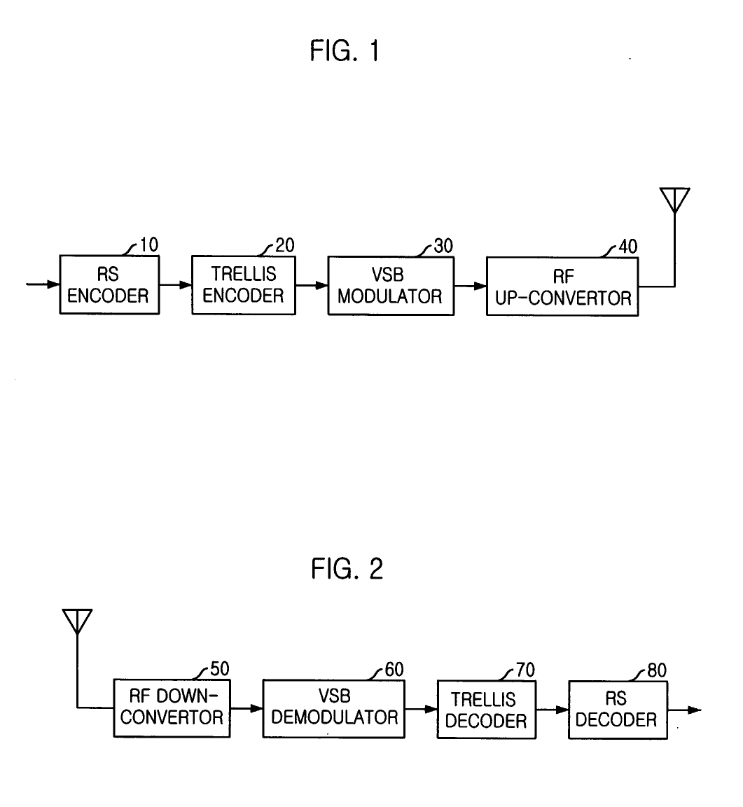

FIG. 1 is a block diagram of a vestigial sideband (VSB) digital broadcasting transmission system in accordance with a preferred embodiment of the present invention.

At first, a reed-solomon (RS) encoder 10 and a trellis encoder 20 produces a channel code of receiving signals. Specially, the trellis encoder 20 reduces the errors to a certain error range for the RS encoder 10. The RS encoder 10 completely eliminates the errors reduced by the trellis encoder 20. After reducing, an output signal of the trellis encoder 20 is transmitted by passing through a vestigial side band (VSB) modulator 30, a radio frequency (RF) up-converter 40 and an antenna.

FIG. 2 is a diagram illustrating a structure of receiver in a VSB transmission system in accordance with a preferred embodiment of the present invention.

Referring to FIG. 2, a signal received through an antenna becomes a baseband-receiving signal by passing through a radio frequency (RF) down-converter 50 and a vestigial side band (VSB) demodulator 60.

After the signal became the baseband-receiving signal, a trellis decoder 70 and a reed-solomon (RS) decoder 80 decodes a channel code to an original signal. The trellis decoder 70 is built according to a construction of the trellis encoder 20 in FIG. 1. That is, a hard decision or a soft decision viterbi decoder can be used as the trellis decoder 70 in FIG. 2.

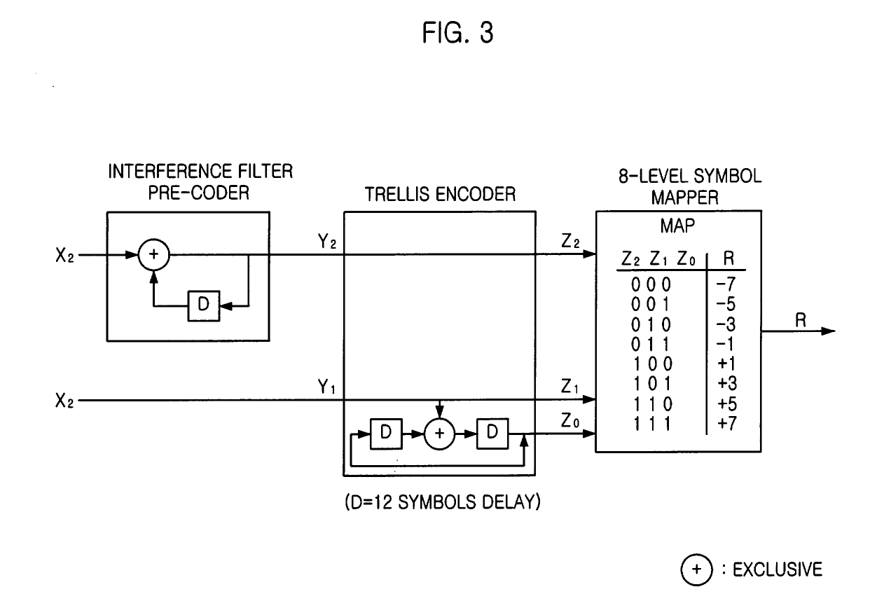

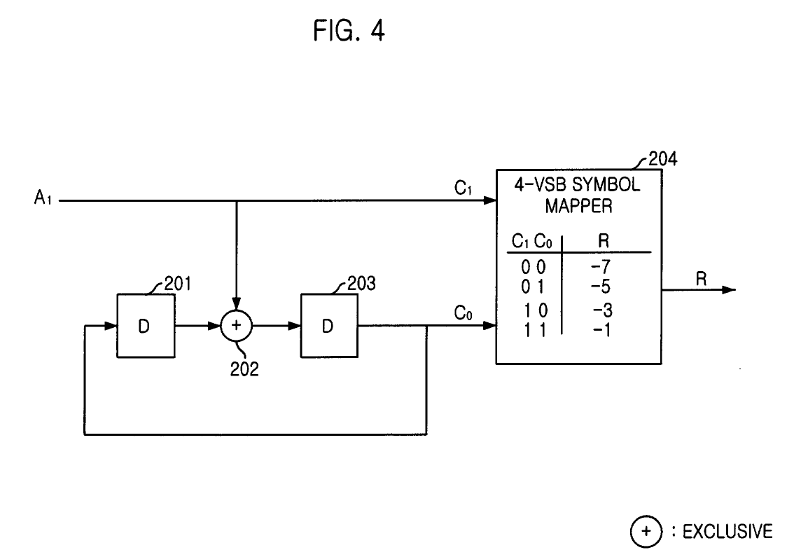

The trellis encoder 20 in FIG. 1 has different structure according to 8-VSB and 4-VSB and the different structures are shown in FIGS. 3 and 4. The trellis encoder 20 having a structure of FIG. 4 is a major element of an embodiment of the present invention. For detailed explanation, FIGS. 3 and 4 are compared as follows.

FIG. 3 is a block diagram illustrating a structure of the trellis encoder 20 of a transmitter in an advanced television system committee (ATSC) 8-VSB transmission system. An interference filter pre-coder for reducing interference between channels and input signals X1, X2 are not related to the embodiment of the present invention therefore, the interference filter pre-coder is not explained here.

A trellis encoder having a 2/3 code rate generates 3-bit output (Z₀, Z₁, Z₂) with 2-bit input (X₁, X₂) in the baseband. The 3-bit output can represent eight information and the eight information are correspondence to symbols such as {−7, −5, −3, −1, 1, 3, 5, 7}. An output of a symbol mapper gains a frequency spectrum for transmission by passing through the VBS modulator 30.

By implementing the trellis encoder 20 having 2/3 code rate, the number of bits for transmission is increased from 2-bit to 3-bit so an output symbol can be represented by eight levels. Therefore, a noise margin of the same transmitting power becomes decreased since a gap between levels is 2. However, since an effective distance between symbols increases due to the conversion of a hamming distance into a Euclidean distance by the trellis coded modulation, the TOV is increased.

A 4-VSB modulation method using the trellis encoder 20 of the present invention is embodied based on the fact mentioned above.

The 4-VSB modulation method according to the present invention is described as follows. The trellis decoder 20 having 1/2 code rate generates a 2-bit output signal with a 1-bit input signal by using two delayers 201, 203 and binary adder 202. Four types of signal level are generated by the 2-bit output signal. The four types of signal levels are mapped to 4 different symbol constellations in a 4-VSB symbol mapper 204. After mapping the 4-VSB symbols, a VSB modulator 30 modulates the four symbol values to VSB spectrums for transmission.

Two of the delayer 210 and 203 and one of the binary adder 202 are used in the preferred embodiment of the present invention, however, the number of the delayer and binary adder is not restricted for embodying the present invention.

In the FIG. 4, the 4-VSB modulator 30 equips the trellis encoder 20 having 1/2 decoding rate to generate a 2-bit output (C₀, C₁) with a 1-bit input )A₁). That is, the 2-bit output is gained from two delayers 201 and 203 and a binary adder 202. The output signal (C₀, C₁) can be expressed as four types of information and those are converted to symbols (R) of {−3, −1, 1, 3} in the symbol mapper 204. Also, the VSB modulator 30 converts the signal to desired VSB spectrum. In here, for comparing 4-VSB symbol and 8-VSB symbol, the same transmission power is supplied. Therefore, output symbol constellations of 4-VSB modulation are {−6.03, −2.01, 2.01, 6.03} in case that the same power is supplied based on levels of 8-VSB output symbol.

The symbol implemented in the 4-VSB modulation has a 4.02 for a gab between neighbor symbol constellations. It is two times wider comparing to the 8-VSB modulation method and improves the noise margin of the symbols.

The noise margin of symbols of the 4-VSB and the 8-VSB modulator are closely related to the symbol error probability, which is the possibility of error occurrence due to the noise in the transmission channel. The probability of symbol error affects critically to operations of the trellis decoder 20 and the operation of the trellis decoder 20 affects the receiving performance of the VSB transmission system. Therefore, it is very important factor to decrease the probability of symbol error for improving the receiving performance.

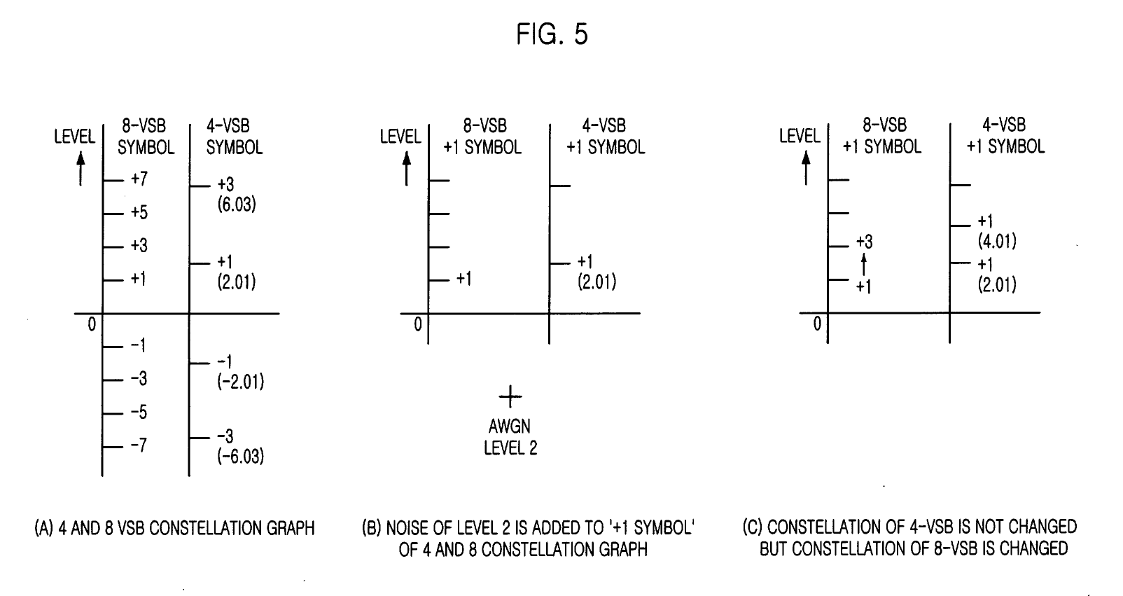

FIG. 5 is graphs illustrating the noise margin of output symbols obtained by the 4-VSB modulation and 8-VSB modulation. That is, in symbols of the 4-VSB and the 8-VSB (a), if a noise of level 2 is added +1 symbol (b), there is no difference in the 4-VSB but the 8-VSB is distorted (c).

As mentioned above, the 4-VSB system of the present invention can improve the reliability of the symbols compared with 8-VSB system equipping the conventional 2/3 code rate trellis encoder and therefore, the receiving performance of the VSB transmission system can be improved.

The present invention, as mentioned above, can be implemented as instructions and can be stored in a computer readable record medium such as a ROM, RAM, CD-ROM, floppy disk, hard disk and optical magnetic disk.

As mentioned above, the present invention can improve the receiving performance of the VSB transmission system in a mobile environment by applying the trellis encoder with 1/2 code rate to the VSB broadcasting transmission system, which decreases the minimum signal-to-noise ratio for recovering an original signal.

While the present invention has been described with respect to certain preferred embodiments, it will be apparent to those skilled in the art that various changes and modifications may be made without departing from the scope of the invention as defined in the following claims.

What is claimed is:

1. A baseband encoding apparatus in a vestigial sideband transmission system, comprising:
a trellis encoder having a 1/2 code rate for generating a 2-bit output signal based on a 1-bit input signal and generating 4 types of signal levels in baseband by using the 2-bit output signal, wherein the trellis encoder includes M number of delayers and N number of binary adders and M and N are natural numbers; and
a symbol mapper for converting the 4 types of the signal levels of the trellis encoder to symbols and generating 4 types of output symbols.

2. The apparatus as recited in claim 1, wherein the 4 types of output symbols are modulated to a vestigial sideband (VSB) spectrum to be transmitted by a vestigial sideband (VSB) modulator and constellations of output symbol generated by a 4-VSB modulation has a gap of 4.02 between adjacent symbols as like as {−6.03, −2.01, 2.01, 6.03}, when the 4-VSB modulation uses the same electric power as a 8-VSB modulation.

3. A method for modulating frequency in a vestigial sideband transmission system, comprising the steps of:
a) generating a 2-bit output signal based on a 1-bit input signal by using M natural number of delayers and N natural number of binary adders and generating 4 types of output levels by using said 2-bit output signals;
b) converting the 4 types of output levels to symbols; and
c) converting the symbols generated in step b) to frequency spectrums to be transmitted.

4. The method as recited in claim 3, wherein the 4 symbol values are modulated to a vestigial sideband (VSB) spectrum for transmitting by a vestigial sideband (VSB) modulator and a constellations of output symbol generated by a 4-VSB modulation has a gap of 4.02 between adjacent symbols as like as {−6.03, −2.01, 2.01, 6.03}, when the 4-VSB modulation uses the same electric power as a 8-VSB modulation.

5. The method as recited in claim 3, wherein in the step c), the symbols generated by a trellis encoder having a 1/2 code rate are 4-VSB modulated.

6. A computer readable record medium storing instructions for executing the method for frequency modulation in a VSB transmission system, comprising the functions of:
a) generating a 2-bit output signal based on a 1-bit input signal by using M natural number of delayers and N natural number of binary adders and generating 4 types of output levels by using said 2-bit output signals;
b) converting the 4 types of output levels to symbols; and
c) converting the symbols generated in step b) to frequency spectrums to be transmitted.
